(19) United States
(12) Patent Application Publication
(10) Pub. No.: US 2022/0208908 A1
(43) Pub. Date: Jun. 30, 2022

(54) DISPLAY DEVICE AND MANUFACTURING METHOD THEREOF

(71) Applicant: LG DISPLAY CO., LTD., Seoul (KR)

(72) Inventors: Hyeongseok KIM, Paju-si (KR); Jaehwan MYUNG, Paju-si (KR)

(73) Assignee: LG DISPLAY CO., LTD., SEOUL (KR)

(21) Appl. No.: 17/558,545

(22) Filed: Dec. 21, 2021

(30) Foreign Application Priority Data
Dec. 31, 2020 (KR) 10-2020-0189884

(51) Int. Cl. H01L 27/32

(52) U.S. Cl. CPC H01L 27/3246; H01L 2227/323

(57) ABSTRACT

A display device includes a substrate on which pixels are arranged; a first bank which is disposed on the substrate, extends in a row direction and in a column direction, and defines a light emitting area of the pixels; a second bank which is disposed on the first bank, extends in the column direction, and separates adjacent pixel columns; and a third bank which is disposed on both sides of the first bank.

### CROSS-REFERENCE TO RELATED APPLICATION

The present application claims the priority of Korean Patent Application No. 10-2020-0189884, filed on Dec. 31, 2020, which is hereby incorporated by reference in its entirety for all purposes.

### BACKGROUND

### Field of the Disclosure

The present disclosure relates to a display device and a manufacturing method thereof.

### Description of the Background

With the development of information-oriented society, various types of display devices are being developed. Among a variety of display devices, a liquid crystal display (LCD) and an organic light emitting display (OLED) are mostly in the market.

An organic light emitting device constituting the OLED emits light by itself without a separate light source, and thus, the OLED can be thinner and lighter. Also, the OLED shows high quality characteristics such as low power consumption, a high luminance, and high response speed, etc.

Recently, a technology for forming a light emitting layer of an organic light emitting device through a solution process using an inkjet apparatus is being developed. The solution process is performed by applying a solution for forming a light emitting layer on a set region and then drying the solution.

### SUMMARY

The present disclosure is to provide a display device capable of eliminating a thickness deviation of a light emitting layer of an organic light emitting device manufactured by using a solution process and capable of improving flatness, and a manufacturing method thereof.

The present disclosure is also to provide a display device including a hydrophilic bank, a hydrophobic bank disposed on top and side surfaces of the hydrophilic bank, and a manufacturing method thereof.

One aspect of the present disclosure is a display device including: a substrate on which pixels are arranged; a first bank which is disposed on the substrate, extends in a row direction and in a column direction, and defines a light emitting area of the pixels; a second bank which is disposed on the first bank, extends in the column direction, and separates adjacent pixel columns; and a third bank which is disposed on both sides of the first bank.

The first bank has a reverse tapered side surface, and the second bank has a tapered side surface.

A hole which is not exposed upward is formed on the circumference of the reverse tapered side surface of the first bank, the third bank is disposed within the hole.

The third bank includes one surface which faces the reverse tapered side surface of the first bank; and the other surface which is opposite to the first bank.

The other surface has a tapered shape or a concave shape.

The one surface is disposed in contact with or adjacent to the first bank.

The third bank has a hydrophilic property, or at least one region of the third bank has a hydrophobic property.

The display device further includes: a first electrode; a light emitting layer formed on the first electrode; and a second electrode formed on the light emitting layer. The light emitting layer has a multilayer thin film structure in which at least one thin film is stacked.

A height of a surface in an edge region of at least one of the at least one thin film is greater than a height of a surface in a central region.

The edge region is disposed within the hole.

An edge region of an uppermost stacked thin film among the at least one thin film is in contact with the second bank, and a top surface including the edge region is formed flat.

The display device further includes an auxiliary electrode which is connected to a low potential driving voltage through a contact hole. The second bank and the third bank are formed to cover the top and entire side surface of the first bank in the vicinity of the contact hole.

Another aspect is a manufacturing method of the display device. The manufacturing method includes: forming a first bank which extends on a substrate in a row direction and in a column direction and defines light emitting areas of pixels; forming a second bank which extends on the first bank in the column direction, and separates adjacent pixel columns, and a third bank which is disposed on both sides of the first bank; and forming a light emitting layer by applying an organic light emitting material to each of the pixel columns.

The forming the second bank and the third bank includes: applying a solution for forming the second bank on the first bank; and forming the second bank by patterning the solution through a photolithography process.

A portion of the solution for forming the second bank is separated to a side surface of the first bank, and the third bank is formed through the photolithography process.

The solution for forming the second bank is formed by mixing a hydrophobic material into a hydrophilic organic insulating material. The hydrophobic material is arranged on a top surface of the second bank during the photolithography process.

The forming the first bank includes: patterning the side surface of the first bank in a reverse tapered shape and forming a hole which is not exposed upward, on the circumference of the reverse tapered side surface of the first bank. The third bank is disposed within the hole.

The forming the second bank and the third bank includes patterning an exposed one side of the third bank in a tapered shape or in a concave shape.

The forming the light emitting layer includes stacking sequentially at least one thin film. A height of a surface in an edge region of at least one of the at least one thin film is greater than a height of a surface in a central region, and the edge region is disposed within the hole.

An edge region of an uppermost stacked thin film among the at least one thin film is in contact with the second bank, and a top surface including the edge region is formed flat.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain the principle of the disclosure.

In the drawings:

FIG. 1 is a block diagram showing a configuration of a display device according to the present disclosure;

FIG. 2 is a circuit diagram of a pixel according to the present disclosure;

FIG. 3 is a schematic cross-sectional view of a display panel according to an aspect of the present disclosure;

FIG. 4 is a schematic plan view of a region of the display panel according to the aspect of the present disclosure;

FIG. 5 is a cross-sectional view taken along line I-I′ of FIG. 4;

FIG. 6 is a cross-sectional view taken along line II-IF of FIG. 4;

FIG. 7 is an enlarged cross-sectional view of a bank shown in FIG. 4;

FIG. 8 is an enlarged cross-sectional view of the bank shown in FIG. 4 according to another aspect of the present disclosure;

FIG. 9 is a view for describing a drying type of a solution according to the aspect of the present disclosure;

FIG. 10 is a schematic view for describing a forming principle of a hydrophobic bank according to the present disclosure; and

FIGS. 11 and 12 are views for describing a method for forming the bank according to the aspect of the present disclosure.

### DETAILED DESCRIPTION

Hereinafter, aspects of the present disclosure will be described with reference to the accompanying drawings. In this specification, when it is mentioned that a component (or region, layer, portion) “is on”, “is connected to”, or “is combined with” another component, terms “is on”, “connected to”, or “combined with” mean that a component may be directly connected to/combined with another component or mean that a third component may be disposed between them.

The same reference numerals correspond to the same components. Also, in the drawings, the thicknesses, ratios, and dimensions of the components are exaggerated for effective description of the technical details. A term “and/or” includes all of one or more combinations that related configurations can define.

While terms such as the first and the second, etc., can be used to describe various components, the components are not limited by the terms mentioned above. The terms are used only for distinguishing between one component and other components. For example, the first component may be designated as the second component without departing from the scope of rights of various aspects. Similarly, the second component may be designated as the first component. An expression of a singular form includes the expression of plural form thereof unless otherwise explicitly mentioned in the context.

Terms such as “below”, “lower”, “above”, “upper” and the like are used to describe the relationships between the components shown in the drawings. These terms have relative concepts and are described based on directions indicated in the drawings.

In the present specification, it should be understood that the term “include” or “comprise” and the like is intended to specify characteristics, numbers, steps, operations, components, parts or any combination thereof which are mentioned in the specification, and intended not to previously exclude the possibility of existence or addition of at least one another characteristics, numbers, steps, operations, components, parts or any combination thereof.

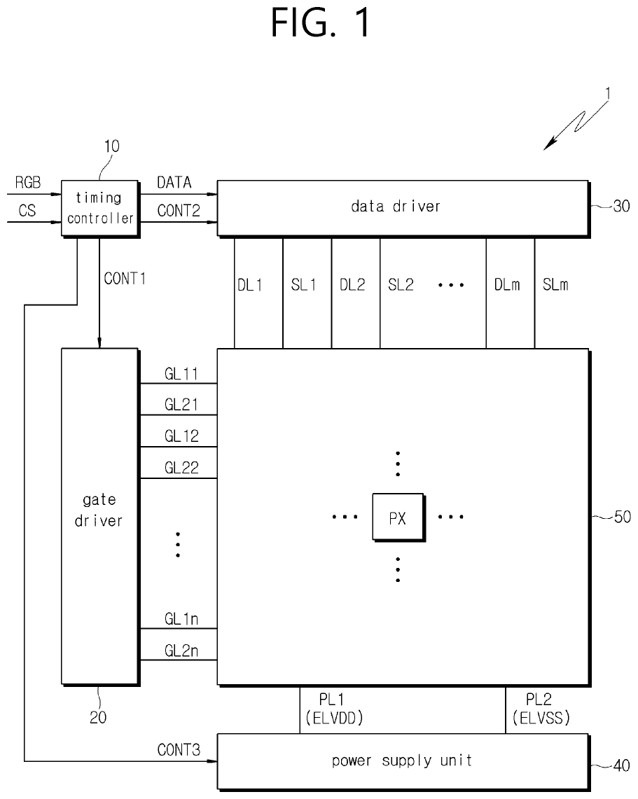

FIG. 1 is a block diagram showing a configuration of a display device according to the present disclosure.

Referring to FIG. 1, a display device 1 includes a timing controller 10, a gate driver 20, a data driver 30, a power supply unit 40, and a display panel 50.

The timing controller 10 may receive an image signal RGB and a control signal CS from the outside. The image signal RGB may include a plurality of grayscale data. The control signal CS may include, for example, a horizontal synchronization signal, a vertical synchronization signal, and a main clock signal.

The timing controller 10 may process the image signal RGB and the control signal CS in conformity with operation conditions of the display panel 50, and then may generate and output an image data DATA, a gate driving control signal CONT1, a data driving control signal CONT2, a power supply control signal CONT3.

The gate driver 20 may be connected to pixels PX of the display panel 50 through a plurality of first gate lines GL11 to GL1n. The gate driver 20 may generate gate signals on the basis of the gate driving control signal CONT1 output from the timing controller 10. The gate driver 20 may provide the generated gate signals to pixels PX through the plurality of first gate lines GL11 to GL1n.

According to various aspects, the gate driver 20 may be further connected to the pixels PX of the display panel 50 through a plurality of second gate lines GL21 to GL2n. The gate driver 20 may provide sensing signals to the pixels PX through the plurality of second gate lines GL21 to GL2n. The sensing signal may be provided to measure characteristics of a driving transistor and/or a light emitting device provided within the pixels PX.

The data driver 30 may be connected to the pixels PX of the display panel 50 through a plurality of data lines DL1 to DLm. The data driver 30 may generate data signals based on the image data DATA and the data driving control signal CONT2 output from the timing controller 10. The data driver 30 may provide the generated data signals to the pixels PX through the plurality of data lines DL1 to DLm.

According to various aspects, the data driver 30 may be further connected to the pixels PX of the display panel 50 through a plurality of sensing lines SL1 to SLm. The data driver 30 may provide a reference voltage (or a sensing voltage, an initialization voltage) to the pixels PX through the plurality of sensing lines SL1 to SLm or may sense the state of the pixels PX on the basis of electrical signals fed back from the pixels PX.

The power supply unit 40 may be connected to the pixels PX of the display panel 50 through a plurality of power lines PL1 and PL2. The power supply unit 40 may generate a driving volage which is to be supplied to the display panel 50 on the basis of the power supply control signal CONT3. The driving volage may include, for example, a high potential driving voltage ELVDD and a low potential driving voltage ELVSS. The power supply unit 40 may supply the generated driving voltages ELVDD and ELVSS to the pixels PX through corresponding power lines PL1 and PL2.

A plurality of the pixels PX (or referred to as subpixels) are disposed on the display panel 50. The pixels PX may be arranged, for example, in a matrix form on the display panel 50.

Each of pixels PX may be electrically connected to a corresponding gate line and data line. The pixels PX may emit light with a luminance which corresponds to the gate signal and the data signal provided through the first gate lines GL11 to GL1n and the data lines DL1 to DLm.

Each pixel PX may represent any one of a first to a third colors. In the aspect, each pixel PX may represent any one of red, green, and blue colors. In another aspect, each pixel PX may represent any one of cyan, magenta, and yellow colors. In various aspects, the pixels PX may be configured to represent any one of four or more colors. For example, each pixel PX may represent any one of red, green, blue, and white colors.

The timing controller 10, the gate driver 20, the data driver 30, and the power supply unit 40 may be each composed of a separate integrated circuit (IC), or may be configured as an IC in which at least some of them are integrated. For example, at least one of the data driver 30 and the power supply unit 40 may be configured as an integrated circuit integrated with the timing controller 10.

Also, although the gate driver 20 and the data driver 30 are shown in FIG. 1 as separate components from the display panel 50, at least one of the gate driver 20 and the data driver 30 may be implemented in an in-panel method where it is formed integrally with the display panel 50. For example, the gate driving part 20 may be formed integrally with the display panel 50 in a gate-in-panel (GIP) method.

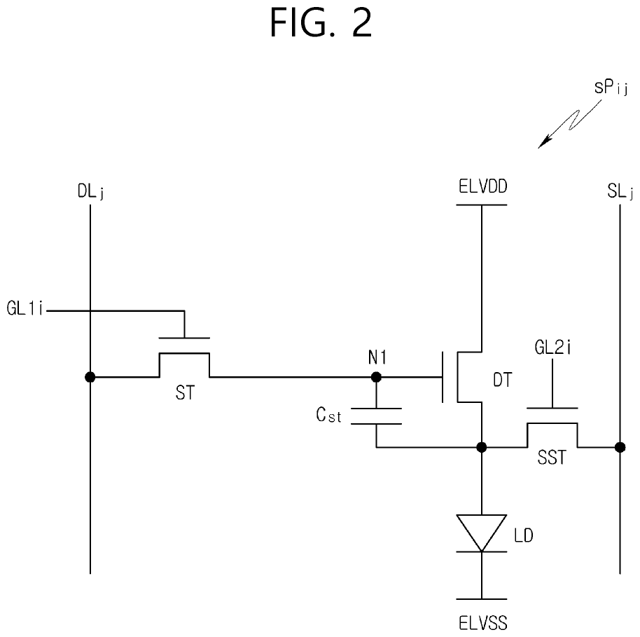

FIG. 2 is a circuit diagram showing an aspect of a pixel shown in FIG. 1. FIG. 2 shows the pixel PXij connected to the first i-th gate line GL1i and the j-th data line DLj as an example.

Referring to FIG. 2, the pixel PX includes a switching transistor ST, a driving transistor DT, a sensing transistor SST, a storage capacitor Cst, and a light emitting device LD.

A first electrode (e.g., a source electrode) of the switching transistor ST is electrically connected to the j-th data line DLj, and a second electrode (e.g., a drain electrode) of the switching transistor ST is electrically connected to a first node N1. A gate electrode of the switching transistor ST is electrically connected to the first i-th gate line GL1i. The switching transistor ST is turned on when a gate signal of a gate-on level is applied to the first i-th gate line GL1i, and transmits the data signal applied to the j-th data line DLj to the first node N1.

A first electrode of the storage capacitor Cst is electrically connected to the first node N1, and a second electrode of the storage capacitor Cst is electrically connected to a first electrode of the light emitting device LD. The storage capacitor Cst may be charged with a voltage corresponding to a difference between the voltage applied to the first node N1 and the voltage applied to the first electrode of the light emitting device LD.

A first electrode (e.g., a source electrode) of the driving transistor DT is configured to receive the high potential driving voltage ELVDD, and a second electrode (e.g., a drain electrode) of the driving transistor DT is electrically connected to the first electrode (e.g., the first electrode) of the light emitting device LD. A gate electrode of the driving transistor DT is electrically connected to the first node N1. The driving transistor DT may be turned on when a gate-on level voltage is applied through the first node N1, and may control the amount of driving current flowing through the light emitting device LD in response to the voltage applied to the gate electrode.

A first electrode (e.g., a source electrode) of the sensing transistor SST is electrically connected to the j-th sensing line SLj, and a second electrode (e.g., a drain electrode) of the sensing transistor SST is electrically connected to the first electrode (e.g., a first electrode) of the light emitting device LD. A gate electrode of the sensing transistor SST is electrically connected to the second i-th gate line GL2i. The sensing transistor SST is turned on when a sensing signal of a gate-on level is applied to the second i-th gate line GL2i, and transmits a reference voltage applied to the j-th sensing line SLj to the first electrode of the light emitting device LD.

The light emitting device LD outputs light corresponding to the driving current. The light emitting device LD may output light corresponding to any one of red, green, blue, and white colors. The light emitting device LD may be an organic light emitting diode (OLED) or a micro inorganic light emitting diode having a size in a range from micro scale to nano scale. However, the present aspect is not limited thereto. Hereinafter, the technical spirit of the present disclosure will be described with reference to the aspect in which the light emitting device LD is composed of the organic light emitting diode.

In the aspect, the structure of the pixels PXij is not limited to what is shown in FIG. 2. According to the aspect, the pixels PXij may further include at least one element for compensating a threshold voltage of the driving transistor DT or initializing the voltage of the gate electrode of the driving transistor DT and/or the voltage of the first electrode of the light emitting device LD.

FIG. 2 shows an example in which the switching transistor ST, the driving transistor DT, and the sensing transistor SST are NMOS transistors. However, the present disclosure is not limited thereto. For example, at least some or all of the transistors constituting each pixel PX may be composed of a PMOS transistor. In various aspects, each of the switching transistor ST, the driving transistor DT, and the sensing transistor SST may be implemented with a low temperature poly silicon (LTPS) thin film transistor, an oxide thin film transistor, or a low temperature polycrystalline oxide (LTPO) thin film transistor.

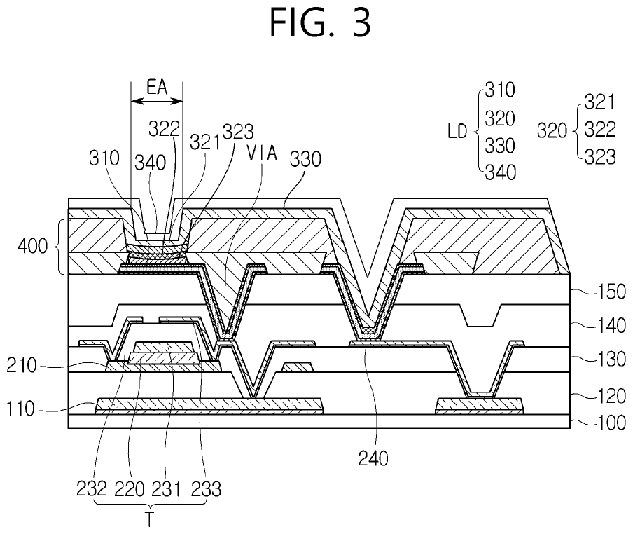

FIG. 3 is a schematic cross-sectional view of a display panel according to the present disclosure. Particularly, FIG. 3 shows schematically a stack structure of an area in which the pixels PX are disposed within the display panel 50.

Referring to FIG. 3, the display panel 50 may include a substrate 100, a circuit element layer formed on the substrate 100 and provided with at least one circuit element, and a light emitting device layer including the light emitting device LD.

The substrate 100 is a base material of the display panel 50 and may be a light-transmitting substrate. The substrate 100 may be a rigid substrate including glass or tempered glass or a flexible substrate made of plastic.

The circuit element layer is formed on the substrate 100 and may include circuit elements (e.g., transistors, capacitors, etc.) and wirings which constitute the pixel PX.

In the aspect, a light shielding layer 110 may be formed on the substrate 100. The light shielding layer 110 is disposed to overlap with, on a plane, an active layer 210 of a transistor T, particularly, a channel region formed in the active layer 210, thereby protecting the elements from external light.

The light shielding layer 110 may be covered by a buffer layer 120. The buffer layer 120 can prevent diffusion of ions or impurities from the substrate 100 and block moisture penetration.

The active layer 210 may be formed on the buffer layer 120. The active layer 210 may be formed of a silicon-based semiconductor material or an oxide-based semiconductor material. The active layer 210 may include a source region including p-type impurities, a drain region including n-type impurities, and the channel region formed between the source region and the drain region.

A gate insulating layer 220 may be formed on the active layer 210. The gate insulating layer 220 may be formed on the channel region of the active layer 210. The gate insulating layer 220 may be made of silicon oxide (SiOx), silicon nitride (SiNx) or may be a multilayer thereof.

A gate electrode 231 may be formed on the gate insulating layer 220. The gate electrode 231 may be disposed at a position corresponding to the channel region of the active layer 210.

An interlayer insulating layer 130 may be formed on the gate electrode 231. The interlayer insulating layer 130 may cover the gate electrode 231 and regions of the active layer 210 which is not covered by the gate electrode 231, and regions of the buffer layer 120 in which the active layer 210 is not formed. The interlayer insulating layer 130 may be made of silicon oxide layer (SiOx), silicon nitride layer (SiNx) or may be a multilayer thereof.

A source electrode 232 and a drain electrode 233 may be formed on the interlayer insulating layer 130. The source electrode 232 and the drain electrode 233 may be connected to the source region and the drain region of the active layer 210 respectively through a contact hole which pass through the interlayer insulating layer 130.

The gate electrode 231, the source electrode 232, the drain electrode 233, and the active layer 210 corresponding thereto may constitute the transistor T. The transistor T may be, for example, the driving transistor DT or the switching transistor ST. In FIG. 3, the driving transistor DT in which the drain electrode 233 is connected to the first electrode 310 of the light emitting device LD is shown as an example.

A bridge electrode 240 may be further formed on the interlayer insulating layer 130. The bridge electrode 240 may be connected to the light shielding layer 110 through a contact hole which passes through the interlayer insulating layer 130 and the buffer layer 120. The bridge electrode 240 may be connected, via the light shielding layer 110, to the power line PL2 which applies the low potential driving voltage ELVSS.

A passivation layer 140 may cover the source electrode 232, the drain electrode 233, and the bridge electrode 240 which are formed on the interlayer insulating layer 130. The passivation layer 140 is an insulating layer to protect the devices thereunder, and may be formed of an inorganic material or an organic material.

An overcoat layer 150 may be formed on the passivation layer 140. The overcoat layer 150 may be a planarization layer for reducing a step difference in the structure thereunder. The overcoat layer 150 may be formed of an organic material such as polyimide, benzocyclobutene series resin, acrylate, etc.

The light emitting device layer is formed on the overcoat layer 150 and includes the light emitting devices LDs. The light emitting device LD includes the first electrode 310, a light emitting layer 320, and a second electrode 340. The first electrode 310 may be an anode electrode and the second electrode 340 may be a cathode electrode.

The first electrode 310 is formed on the overcoat layer 150. The first electrode 310 is connected to the drain electrode 233 of the transistor T through a via hole VIA which pass through the overcoat layer 150 and the passivation layer 140. When the first electrode 310 includes a reflective layer, the first electrode 310 may be formed as a triple layer including a transparent conductive layer/a reflective layer/a transparent conductive layer. For example, the first electrode 310 may be formed as a triple layer including ITO/Ag/ITO.

An auxiliary electrode 341 may be further formed on the overcoat layer 150. The auxiliary electrode 341 may be made of the same material as the first electrode 310. For example, the auxiliary electrode 341 may have the same triple-layer structure as that of the first electrode 310. Alternatively, the auxiliary electrode 341 may have a structure in which at least one layer among the triple layers of the first electrode 310 is omitted. The auxiliary electrode 341 may be connected to the bridge electrode 240 through a contact hole which pass through the overcoat layer 150 and the passivation layer 140 and may receive the low potential driving voltage ELVSS.

A bank 400 is further formed on the overcoat layer 150. The bank 400 may be a defining layer which defines a light emitting area EA of the pixel PX. The bank 400 is formed to cover a portion of the edge of the first electrode 310, and the exposed region of the first electrode 310 which is not covered by the bank 400 can be defined as the light emitting area EA of the pixel PX. The first electrode 310, the light emitting layer 320, and the second electrode 340 are stacked within the light emitting area EA such that they are in direct contact with each other. Also, the bank 400 may be formed to expose a region of the auxiliary electrode 341.

A light emitting layer 320 is formed on the first electrode 310. The light emitting layer 320 is formed on some regions of the first electrode 310 which is exposed without being covered by the bank 400. That is, the light emitting layer 320 may be formed in the light emitting area EA defined by the bank 400.

The light emitting layer 320 may have a multilayer thin film structure including a light generating layer. For example, the light emitting layer 320 may include a hole injection layer 323, a hole transport layer 322, and a light generating layer 321.

In the aspect, the light emitting layer 320 may be formed by a solution process using inkjet apparatuses or the like. That is, the light emitting layer 320 may be formed by applying (or dropping) an organic light emitting material, for example, a solution, to a region surrounded by the bank 400, and by drying the applied solution.

When the light emitting layer 320 is formed by the solution process, a difference in surface height may occur (or pile-up) between a central region of the light emitting layer 320 and an edge region adjacent to the bank 400 by a tension between the solution and the bank 400. For example, the light emitting layer 320 may be formed in a concave shape which having the smallest thickness in its central portion and the largest thickness in its region which is in contact with the bank 400.

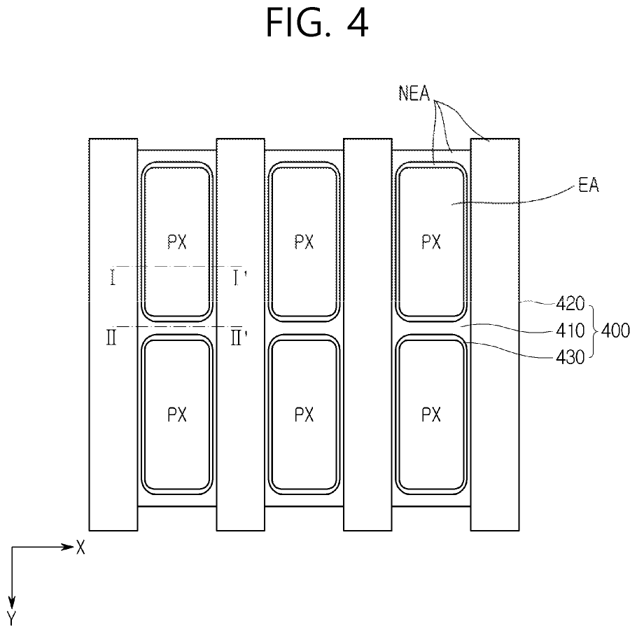

The non-uniformity of the surface of the light emitting layer 320 can reduce the luminous efficiency of the light emitting device LD and can deteriorate the performance of the display panel 50. In order to prevent such problems, the bank 400 includes a first bank 410 having a hydrophilic property, a second bank 420 which is disposed on the top and side of the first bank and has at least one hydrophobic region, and a third bank 430. A specific configuration of the bank 400 will be described in detail below with reference to FIGS. 4 to 11.

An electron transport layer 330 may be included. The electron transport layer 330 may be formed on the entire surface of the display panel 50.

The second electrode 340 may be formed on the entire surface of the display panel 50. That is, the second electrode 340 may be formed to cover the bank 400, the light emitting layer 320, and the auxiliary electrode 341. The second electrode 340 may be connected to the auxiliary electrode 341 through a contact hole. The low potential driving voltage ELVSS which is applied to the auxiliary electrode 341 is applied to the light emitting device LD through the second electrode 340.

The electron transport layer 330 and the second electrode 340 can be deposited on the display panel 50 by an evaporation deposition method such as thermal deposition or by a physical vapor deposition method such as a sputtering method.

FIG. 4 is a schematic plan view of a region of the display panel.

The display panel 50 may include the pixels PX which represent any one of a first to a third colors. For example, the pixels PX may include first pixels representing a red color, second pixels representing a green color, and third pixels representing a blue color. Here, pixels representing the same color may be disposed in one pixel column on the display panel 50. For example, the first pixels may be disposed in a first pixel column, the second pixels may be disposed in a second pixel column, and the third pixels may be disposed in a third pixel column.

The bank 400 is formed around (on the circumference of) each pixel PX. Regions surrounded by the bank 400 can be defined as the light emitting area EA of each pixel PX. Each light emitting area EA is surrounded by a non-light emitting area NEA. The banks 400 defining the light emitting areas EA may be formed in the non-light emitting area NEA.

The bank 400 may be composed of banks with at least two layers having hydrophilicity and/or hydrophobicity. For example, the bank 400 may include the first bank 410 having hydrophilicity, the third bank 430, and the second bank 420 having at least one region having hydrophobicity.

The first bank 410 is configured to surround the respective pixels PX. In other words, the first bank 410 is disposed around the light emitting area EA of each pixel PX. The first bank 410 may have a grid shape extending between pixel rows and between pixel columns. That is, the first bank 410 may extend between the pixel rows in a row direction X as well as between the pixel columns in a column direction Y.

Since the first bank 410 has a hydrophilic property, when a solution for forming the light emitting layer 320 is applied on the bank 400, the solution may spread along the side surface of the first bank 410.

The second bank 420 is formed on the first bank 410. The second bank 420 may be a defining layer which separates the respective pixel columns. The second bank 420 is formed on the first bank 410 which extends in the column direction Y between the pixel columns. At least one region of the second bank 420 has a hydrophobic property. When the solution for forming the light emitting layer 320 is applied on the display panel 50, the solution is separated from each other between the pixel columns by the second hydrophobic bank 420. Accordingly, the second bank 420 can prevent color mixing between the pixel columns.

The third bank 430 is formed on a side surface of the first bank 410. The third bank 430 may be formed on both sides of the first bank 410 which extends in the column direction Y between the pixel columns in the same manner as the second bank 420. At least one region of the third bank 430 may have a hydrophobic property.

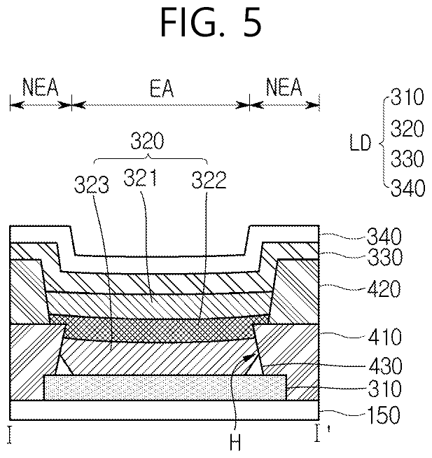

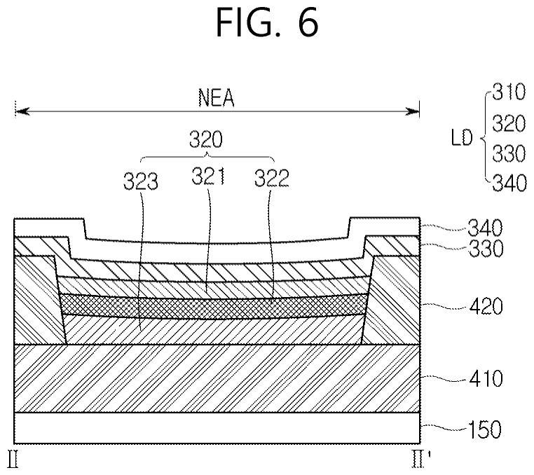

FIG. 5 is a cross-sectional view taken along line I-I′ of FIG. 4, and FIG. 6 is a cross-sectional view taken along line II-IF of FIG. 4. For convenience of description, FIGS. 5 and 6 show a portion of the light emitting device layer disposed on the overcoat layer 150. However, it should be understood that the components described with reference to FIG. 3 can be disposed above and below the shown light emitting device layer.

The first electrode 310 is formed on the overcoat layer 150. The bank 400 is formed to cover a portion of the edge of the first electrode 310, and the exposed region of the first electrode 310 which is not covered by the bank 400 can be defined as the light emitting area EA of the pixel PX.

The bank 400 may include the first bank 410 having hydrophilicity, the third bank 430, and the second bank 420 having at least one region having hydrophobicity.

The first bank 410 has a hydrophilic property. For example, the first bank 410 may be formed of an inorganic insulating material such as silicon oxide. The first bank 410 is disposed around each light emitting area EA. Here, the first bank 410 may be disposed to cover a portion of an edge of each of the first electrodes 310.

Since the first bank 410 has a hydrophilic property, when a solution for forming the light emitting layer 320 is applied on the bank 400, the solution may spread along the side surface of the first bank 410. Here, the edge of the solution may be confined in a hole H in the side of the first bank 410. Even though pile-up occurs at the edge while the solution dries, the central region of the light emitting layer 320 can have a flat surface because the edge is disposed within the hole H. As a result, the surface flatness of the light emitting layer 320 within the light emitting area EA can be improved, and the luminous efficiency can be improved.

In the aspect, the first bank 410 may have a reverse tapered side surface. Due to the reverse tapered shape of the first bank 410, the hole H which is not exposed upward may be formed on the circumference of the first bank 410.

In the aspect, the height of the first bank 410 may be less than 1 and is not limited thereto. If a reverse taper angle “a” is excessively large, when the second electrode 340 is formed on the display panel 50, the second electrode 340 may be cut off around the bank 400. Also, if the reverse taper angle “a” is excessively small, the second electrode 340 can be prevented from being cut off, but uniformity may be reduced. Accordingly, the reverse taper angle “a” of the first bank 410 can be appropriately selected so as to maintain the continuity and uniformity of the second electrode 340. In the aspect, the reverse taper angle “a” of the first bank 410 may be 40 degrees to 80 degrees, and is not limited thereto.

At least one region of the second bank 420 has a hydrophobic property. In the aspect, the second bank 420 may be patterned through a photolithography process after applying a solution in which a hydrophobic material such as fluorine is mixed with a hydrophilic organic insulating material. The hydrophobic material such as fluorine can move to the top of the bank 420 by light irradiated during the photolithography process, and the top of the bank 420 may have a hydrophobic property. However, the present aspect is not limited thereto, and the entire portion of the second bank 420 may be formed to have a hydrophobic property.

The second bank 420 may have a tapered side surface. As the second bank 420 has a tapered shape, the solution can be more effectively separated between adjacent pixel columns, so that the solution can be prevented from being mixed.

The second bank 420 may be formed to be thicker than the first bank 410, but is not limited thereto. In the region where the first bank 410 and the second bank 420 are stacked, the total thickness of the bank 400 may be 1.5 μm to 2.5 μm. The second bank 420 may be formed to have a narrower width than that of the first bank 410. Here, in order to separate the pixels PX from each other and to prevent color mixing between the pixel columns, the second bank 420 can obtain a predetermined minimum width.

The third bank 430 is formed on a side surface of the first bank 410. The third bank 430 may be disposed to fill a portion of the hole H formed on the circumference of the first bank 410 on both sides, and may have a smaller thickness than that of the first bank 410.

In the aspect, the second bank 420 and the third bank 430 can be formed through a single process. For example, when the second bank 420 is formed on the first bank 410, a portion of the second bank 420 is separated to the side surface of the first bank 410, and thus, the third bank 430 can be formed.

At least one region of the third bank 430 may have a hydrophobic property. However, the present aspect is not limited thereto. For example, when the second bank 420 and the third bank 430 are formed, a hydrophobic material may be disposed only on the top of the second bank 420 positioned relatively higher. In this aspect, the third bank 430 may have only hydrophilic properties.

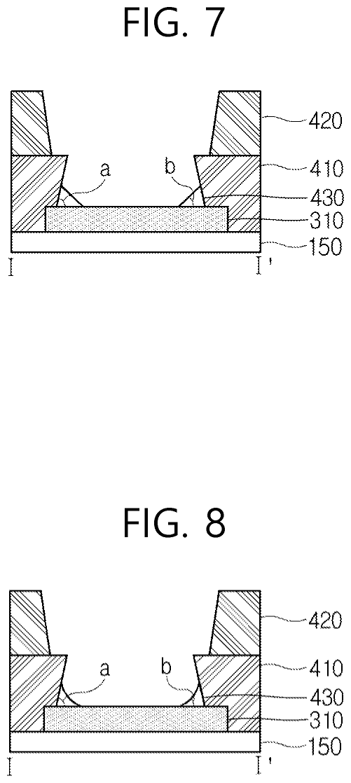

FIG. 7 is an enlarged cross-sectional view according to an aspect of the bank shown in FIG. 4. For convenience of description, FIG. 7 shows a portion of the light emitting device layer disposed on the overcoat layer 150. However, it should be understood that the components described with reference to FIG. 3 can be disposed above and below the shown light emitting device layer.

One surface of the third bank 430 may be disposed in contact with the first bank 410 or may be disposed to face and adjacent to the first bank 410. In the aspect of FIG. 7, the other surface of the third bank 430 may be opposite to the first bank 410 and have a tapered shape. In the aspect, the taper angle “b” of the third bank 430 may be 30 degrees to 60 degrees, and is not limited thereto.

FIG. 8 is an enlarged cross-sectional view according to another aspect of the bank shown in FIG. 4. More specifically, FIG. 8 shows a portion of the light emitting device layer disposed on the overcoat layer 150. However, it should be understood that the components described with reference to FIG. 3 can be disposed above and below the shown light emitting device layer.

In the aspect of FIG. 8, the other surface of the third bank 430 may have a concave shape. When the other surface of the third bank 430 has a concave shape, the third bank 430 may have a relatively large taper angle “b” while having a small thickness, and as a result, the flatness of the second electrode 340 can be increased.

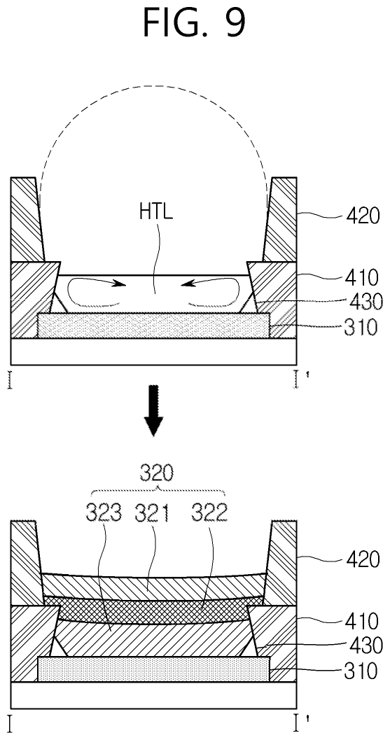

FIG. 9 is a view for describing a drying type of a solution according to the aspect. FIG. 9 shows a portion of the light emitting device layer disposed on the overcoat layer 150. However, it should be understood that the components described with reference to FIG. 3 can be disposed above and below the shown light emitting device layer.

In the aspect, when the second bank 420 and the third bank 430 are formed through the photolithography process, the thickness of the third bank 430 may be determined according to a light exposure time. For example, the shorter the light exposure time is, the smaller the thickness of the third bank 430 may be, and the longer the light exposure time is, the larger the thickness of the third bank 430 may be. The smaller the thickness of the third bank 430 is, the smaller the taper angle “b” is, and the larger the thickness of the third bank 430 is, the larger the taper angle “b” is.

In the above aspect, the light emitting layer 320 can be formed by applying a solution for forming the light emitting layer 320 within a region surrounded by the bank 400, and by drying the applied solution. For example, as shown in FIG. 9, solutions for forming at least one functional layer, for example, the hole transport layer 322 and the hole injection layer 323 together with the light generating layer 321 are applied and dried, respectively, and may be stacked sequentially.

Here, since the first bank 410 has hydrophilicity, the solution can evenly spread in a pixel column direction along the bank 400. Also, since the second bank 420 has hydrophobicity, mixing of the solution between the pixel columns on both sides of the bank 400 is prevented.

As shown on the left of FIG. 9, when the solution is dried, the solution may flow into the hole H of the first bank 410 by Marangoni effect. Then, the edge of the solution can be dried within the hole H. After the solution is dried, due to pile-up phenomena, the surface in the edge region of the light emitting layer 320 is higher than the surface in the central region of the light emitting layer 320. For example, in a thin film stacked under the light emitting layer 320, the thickness in an edge region of the thin film may be greater than a thickness in a central region of the thin film. Here, the edge region is not exposed upward because the edge region is disposed within the hole H of the first bank 410. The central region which is exposed to the top of the first bank 410 and constitutes the light emitting region EA may have a flat surface. As the thin film stacked under the light emitting layer 320 is formed as described above, a thin film which is stacked on the light emitting layer 320 may be, as shown on the right of FIG. 9, formed flat to the edge region.

By the flow of the solution as described above, the light emitting layer 320 formed after the solution is dried may be in contact with the side surface of the first bank 410. In another aspect, since the solution contracts while drying, the light emitting layer 320 may be formed to be spaced apart from the first bank 410.

According to the aspect, in the vicinity of the contact hole which connects the auxiliary electrode 341 to the bridge electrode 240, the second bank 420 may be formed to cover until the side surface of the first bank 410. For example, as shown in FIG. 3, the second bank 420 and the third bank 430 may be integrally formed around the contact hole and may cover the top and side surfaces of the first bank 410.

When the first bank 410 is exposed around the contact hole, the second electrode 340 formed later is separated from the reverse tapered side of the first bank 410 to both sides, and an electrical connection between the second electrode 340 and the auxiliary electrode 341 may be cut off. In order to prevent this problem, the first bank 410 is covered by the second bank 420 having a tapered side around the contact hole, so that the second electrode 340 can be prevented from being cut off, and a short circuit between the auxiliary electrodes 340 and the auxiliary electrode 341 can be prevented.

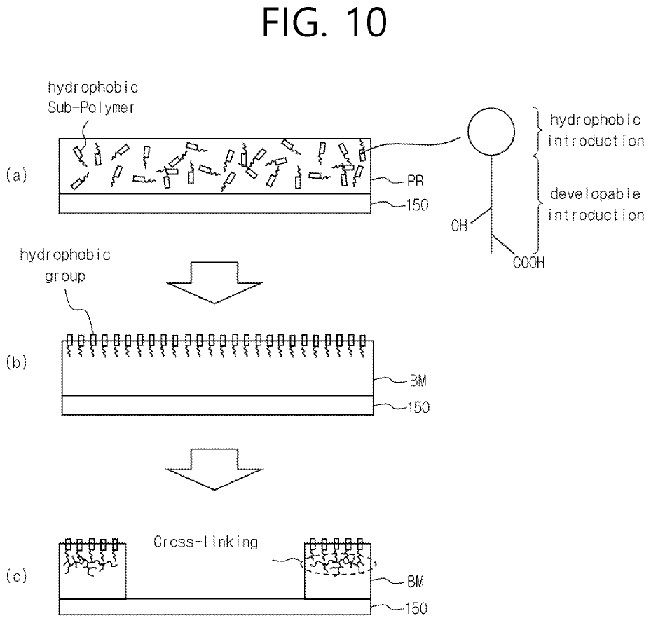

FIG. 10 is a view for describing a forming principle of the hydrophobic bank.

Referring to (a) of FIG. 10, the hydrophobic bank may be formed by processing a solution in which a hydrophobic material is mixed with a hydrophilic organic insulating material through a photolithography process. The hydrophilic organic material is, for example, a polymer-based organic resin, and may be an ink-friendly material used for forming a black matrix. The hydrophobic material may be, for example, a hydrophobic sub-polymer as shown, including a hydrophobic introduction and a developable introduction.

During the photolithography process, a photoresist PR is coated on the applied solution and a drying process is performed (soft baking). Then, as shown in (b) of FIG. 10, the hydrophobic sub-polymer moves to the surface of the solution and is arranged.

Then, a mask is aligned on the solution and light is irradiated to a photosensitive layer BM to form a pattern (exposing pattern). Also, the photoresist layer present on a portion to be etched is removed (developing PR), and a drying process is performed to increase the adhesion of the photoresist (hard baking). Here, a cross link may be formed between a main polymer and the sub-polymer, thereby preventing the dissolution of the solution. A hydrophobic bank having a desired pattern can be formed through the above-described exposure, development, and dry processes.

Additionally, barrier materials of a portion which is not protected by a photosensitizer can be removed through wet or dry etching, and the photosensitive layer can be removed.

The hydrophobic bank can correspond to at least one of the second bank 420 and the third bank 430.

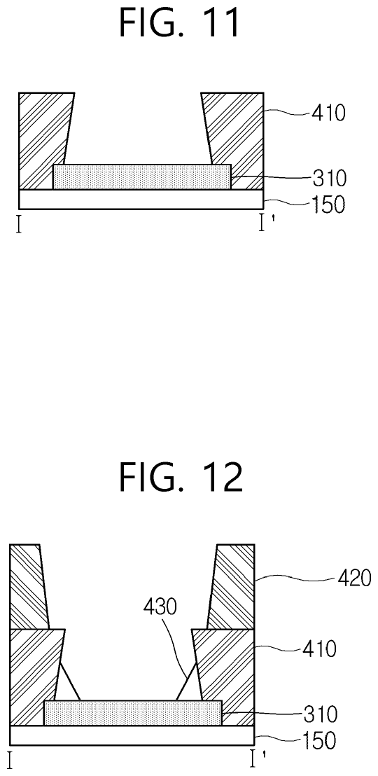

FIGS. 11 and 12 are views for describing a method for forming the bank according to the aspect. For convenience of description, FIGS. 11 and 12 show a portion of the light emitting device layer disposed on the overcoat layer 150. However, it should be understood that the components described with reference to FIG. 3 can be disposed above and below the shown light emitting device layer.

Referring to FIG. 11, after the first electrode 310 is formed on the overcoat layer 150, the first bank 410 may be formed. The first bank 410 may be formed of an inorganic insulating material such as silicon oxide. As described above, the first bank 410 may be patterned in the form of a grid which extends in the row direction X and in the column direction Y in such a way as to define the light emitting area EA of each pixel PX. In this case, the first bank 410 may be patterned to have a reverse tapered side surface.

Then, as shown in FIG. 11, the second bank 420 and the third bank 430 may be formed. In order to form the second bank 420, a solution in which a hydrophobic material such as fluorine is mixed with a hydrophilic organic insulating material may be applied on the first bank 410. Then, the second bank 420 may be patterned on the first bank 410 through the photolithography process.

When the solution for forming the second bank 420 is applied, or during the photolithography process, a portion of the solution is separated to the side surface of the first bank 410 and the third bank 430 can be formed. The third bank 430 may be disposed to contact the side surface of the first bank 410 or may be disposed adjacent to the side surface of the first bank 410.

The second bank 420 and the third bank 430 may have a tapered side surface. In the aspect, the thickness and the taper angle of the third bank 430 can be adjusted according to the light exposure time of the photolithography process.

By the photolithography process, the hydrophobic material mixed with the solution may move to the tops of the second bank 420 and the third bank 430. Accordingly, the tops of the second bank 420 and the third bank 430 can have hydrophobic properties, and the remaining regions may have hydrophilic properties. In the aspect, the hydrophobic material may move to the top only of the second bank 420. In this aspect, the third bank 430 may have only hydrophilic properties. However, the present aspect is not limited thereto.

The method for forming the bank 400 is not limited to the above-described example. For example, independently of the second bank 420, the third bank 430 may be formed through the application of a solution and the photolithography process. Here, the formation process of the third bank 430 may be performed simultaneously with or at a different time from the formation process of the second bank 420.

The display device according to the aspect can improve the luminous efficiency of the organic light emitting device by improving the surface flatness of the light emitting layer formed by a solution process.

It can be understood by those skilled in the art that the aspects can be embodied in other specific forms without departing from its spirit or essential characteristics. Therefore, the foregoing aspects and advantages are merely exemplary and are not to be construed as limiting the present disclosure. It can be understood by those skilled in the art that the aspects can be embodied in other specific forms without departing from its spirit or essential characteristics. Therefore, the foregoing aspects and advantages are merely exemplary and are not to be construed as limiting the present disclosure. The scopes of the aspects are described by the scopes of the following claims rather than by the foregoing description. All modification, alternatives, and variations derived from the scope and the meaning of the scope of the claims and equivalents of the claims should be construed as being included in the scopes of the aspects.

What is claimed is:

1. A display device comprising:
a substrate on which a plurality of pixels are arranged;
a first bank which is disposed on the substrate, extended in row and column directions and defining a light emitting area of the plurality of pixels;
a second bank disposed on the first bank, extended in the column direction, and separating adjacent pixel columns from each other; and
a third bank disposed on both sides of the first bank.

2. The display device of claim 1, wherein the first bank has a reverse tapered side surface, and
wherein the second bank has a tapered side surface.

3. The display device of claim 2, wherein a circumference of the reverse tapered side surface of the first bank has a hole which is not exposed upward, and
wherein the third bank is disposed within the hole.

4. The display device of claim 3, wherein the third bank comprises one surface which faces the reverse tapered side surface of the first bank, and another surface which is opposite to the first bank.

5. The display device of claim 4, wherein the another surface has a tapered shape or a concave shape.

6. The display device of claim 4, wherein the one surface is disposed in contact with or adjacent to the first bank.

7. The display device of claim 3, wherein the third bank has a hydrophilic property, or at least one region of the third bank has a hydrophobic property.

8. The display device of claim 3, further comprising:
a first electrode;
a light emitting layer formed on the first electrode; and
a second electrode formed on the light emitting layer,
wherein the light emitting layer has a multilayer thin film structure in which at least one thin film is stacked.

9. The display device of claim 8, wherein a height of a surface in an edge region of at least one of the at least one thin film is greater than a height of a surface in a central region, and
wherein the edge region is disposed within the hole.

10. The display device of claim 9, wherein an edge region of an uppermost stacked thin film among the at least one thin film is in contact with the second bank, and a top surface comprising the edge region is formed flat.

11. The display device of claim 1, further comprising an auxiliary electrode which is connected to a low potential driving voltage through a contact hole,
wherein the second bank and the third bank are formed to cover the top and entire side surface of the first bank in the vicinity of the contact hole.

12. A display device comprising:
a substrate where a plurality of pixels are defined;
a hydrophilic bank disposed on the substrate and defining a light emitting area of the plurality of pixels;
a first bank having at least a hydrophobic portion, disposed on and extended in parallel with the first hydrophilic bank and separating adjacent pixel columns from each other; and
a second bank having at least a hydrophobic portion, disposed on the hydrophilic bank and surrounding a part of the light emitting area.

13. A manufacturing method of the display device, the manufacturing method comprising:
forming a first bank which extends on a substrate in a row direction and in a column direction and defines light emitting areas of pixels;
forming a second bank which extends on the first bank in the column direction, and separates adjacent pixel columns, and a third bank which is disposed on both sides of the first bank; and
forming a light emitting layer by applying an organic light emitting material to each of the pixel columns.

14. The manufacturing method of claim 13, wherein the forming the second bank and the third bank comprises:
applying a solution for forming the second bank on the first bank; and
forming the second bank by patterning the solution through a photolithography process.

15. The manufacturing method of claim 14, wherein a portion of the solution for forming the second bank is separated to a side surface of the first bank, and the third bank is formed through the photolithography process.

16. The manufacturing method of claim 15,
wherein the solution for forming the second bank is formed by mixing a hydrophobic material into a hydrophilic organic insulating material,
and wherein the hydrophobic material is arranged on a top surface of the second bank during the photolithography process.

17. The manufacturing method of claim 15, wherein the forming the first bank comprises:
patterning the side surface of the first bank in a reverse tapered shape and forming a hole which is not exposed upward, on the circumference of the reverse tapered side surface of the first bank, wherein the third bank is disposed within the hole.

18. The manufacturing method of claim 15, wherein the forming the second bank and the third bank comprises patterning an exposed one side of the third bank in a tapered shape or in a concave shape.

19. The manufacturing method of claim 15, wherein the forming the light emitting layer comprises stacking sequentially at least one thin film, and wherein a height of a surface in an edge region of at least one of the at least one thin film is greater than a height of a surface in a central region, and the edge region is disposed within the hole.

20. The manufacturing method of claim 19, wherein an edge region of an uppermost stacked thin film among the at least one thin film is in contact with the second bank, and a top surface comprising the edge region is formed flat.
